(19) United States
(12) Patent Application Publication
(10) Pub. No.: US 2025/0191846 A1
(43) Pub. Date: Jun. 12, 2025

(54) ELECTRONIC COMPONENT RESISTANT TO CRACKING

(71) Applicant: Murata Manufacturing Co., Ltd., Nagaokakyo-shi (JP)

(72) Inventor: Noriyuki OOKAWA, Nagaokakyo-shi (JP)

(73) Assignee: Murata Manufacturing Co., Ltd., Nagaokakyo-shi (JP)

(21) Appl. No.: 19/059,361

(22) Filed: Feb. 21, 2025

Related U.S. Application Data
(63) Continuation of application No. PCT/JP2023/044667, filed on Dec. 13, 2023.

(30) Foreign Application Priority Data
May 31, 2023 (JP) 2023-089718

(51) Int. Cl. H01G 4/30; H01G 4/232

(52) U.S. Cl. CPC H01G 4/30; H01G 4/232

(57) ABSTRACT

An electronic component includes a base body and a first external electrode to cover a part of an outer surface of the base body. The first external electrode includes no silver component. The first external electrode includes a first underlying electrode to cover an outer surface of the base body. The first underlying electrode includes copper particles and a silicone as a synthetic resin. When the first underlying electrode is bisected into a first part located on the base body side and a second part located on the opposite side to the base body, the average value of the particle sizes of the copper particles in the second part is larger than the average value of the particle sizes of the copper particles in the first part.

### CROSS-REFERENCE TO RELATED APPLICATIONS

This application is a continuation of international application no. PCT/JP2023/044667, filed Dec. 13, 2023, and which claims the benefit of priority to Japanese application no. 2023-089718, filed May 31, 2023. The entire contents of both prior applications are hereby incorporated by reference.

### TECHNICAL FIELD

The present disclosure relates to an electronic component.

### BACKGROUND ART

A conventional electronic component includes a base body, an internal electrode, and an external electrode. The internal electrode is located inside the base body. The external electrode includes a first electrode, a second electrode, and a third electrode. The first electrode covers a part of the outer surface of the base body. The main component of the first electrode is Cu. The second electrode covers the outer surface of the first electrode. The main component of the second electrode is Ag—Pd. The third electrode covers the outer surface of the second electrode. The main components of the third electrode are Ag and a synthetic resin.

### SUMMARY

### Problem to be Solved

A mechanical impact acts on the conventional electronic component described above from the outside, or a thermal impact acts on the electronic component due to a temperature change. Accordingly, a crack and the like may occur in the base body of the electronic component. In the electronic component described above, since the third electrode contains a synthetic resin, the resin component can suppress the impact on the base body. On the other hand, the silver component of the third electrode is easily eluted in a high-temperature and high-humidity environment. Therefore, there is a possibility that the eluted silver component comes into contact and causes migration. Therefore, a technique for suppressing impact on the base body while suppressing migration is required.

### Exemplary Solutions to the Problem

In order to solve at least the above problems, one aspect of the present disclosure is an electronic component including a base body, and an external electrode covering a part of an outer surface of the base body and including no silver component. The external electrode includes an underlying electrode covering an outer surface of the base body, and the underlying electrode includes a copper particle and a synthetic resin. When the underlying electrode is bisected into a first part located on a side closer to the base body and a second part located on a side opposite to the base body, an average value of particle sizes of the copper particle in the second part is larger than an average value of particle sizes of the copper particle in the first part.

### Exemplary Advantageous Effect

In the configuration mentioned above, the external electrode contains no silver component. Therefore, according to the configuration mentioned above, migration can be suppressed as compared with the case where the external electrode contains the silver component. On the other hand, since the particle size of a copper particle of the second part is relatively large, the occurrence of a crack and the like in the base body can also be suppressed.

### BRIEF EXPLANATION OF DRAWINGS

FIG. 1 is a perspective view of an electronic component.

FIG. 2 is a side view of the electronic component.

FIG. 3 is a sectional view taken along line 3-3 in FIG. 2.

FIG. 4 is a schematic sectional view of a first external electrode of the electronic component.

FIG. 5 is an enlarged view of a first underlying electrode of the electronic component.

FIG. 6 is a schematic view of the copper particle in a specific section of the first underlying electrode in the electronic component.

FIG. 7 is a flowchart to outline a method for manufacturing an electronic component.

### DETAILED DESCRIPTION

### <Embodiment of Electronic Component>

Hereinafter, an exemplary embodiment of the electronic component will be described with reference to the drawings. In the drawings, sometimes a component is illustrated while enlarged for the sake of easy understanding. In some cases, the dimension ratio of a component differs from an actual dimension ratio or a dimension ratio in another drawing.

### <Electronic Component>

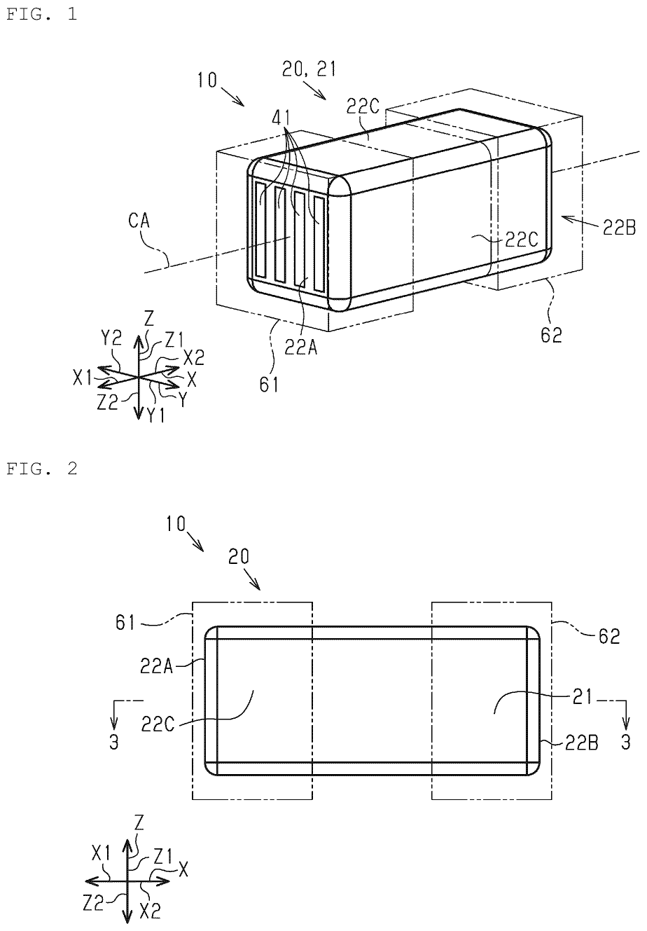

As illustrated in FIG. 1, the electronic component 10 is a multilayer ceramic capacitor. The electronic component 10 includes a base body 20. The base body 20 has a substantially quadrangular prism shape and has a central axis CA. Hereinafter, an axis extending along the central axis CA is referred to as a first axis X. One of the axes orthogonal to the first axis X is defined as a second axis Y. Further, an axis that is orthogonal to both the first axis X and the second axis Y is defined as a third axis Z. In addition, one of the directions along the first axis X is defined as a first positive direction X1, and the direction opposite to the first positive direction X1, of the directions along the first axis X, is defined as a first negative direction X2. In addition, one of the directions along the second axis Y is defined as a second positive direction Y1, and the direction opposite to the second positive direction Y1, of the directions along the second axis Y, is defined as a second negative direction Y2. Further, one of the directions along the third axis Z is defined as a third positive direction Z1, and a direction opposite to the third positive direction Z1, of the directions along the third axis Z, is defined as a third negative direction Z2.

An outer surface 21 of the base body 20 has six planes. The term “surface” of the base body 20 as used herein refers to a part that can be observed as a surface when the entire base body 20 is observed. More specifically, for example, when there are such minute irregularities or steps that fail to be found unless a part of the base body 20 is enlarged and then observed with a microscope or the like, the surface is expressed as a plane or a curved surface. The six planes face different directions. The six planes are roughly divided into a first end surface 22A facing the first positive direction X1, a second end surface 22B facing the first negative direction X2, and four side surfaces 22C. The four side surfaces 22C are a surface facing the third positive direction Z1, a surface facing the third negative direction Z2, a surface facing the second positive direction Y1, and a surface facing the second negative direction Y2, respectively.

Of the outer surface 21 of the base body 20, a boundary portion between two adjacent planes and a boundary portion between three adjacent planes are curved surfaces. That is, the corners of the base body 20 are round chamfered.

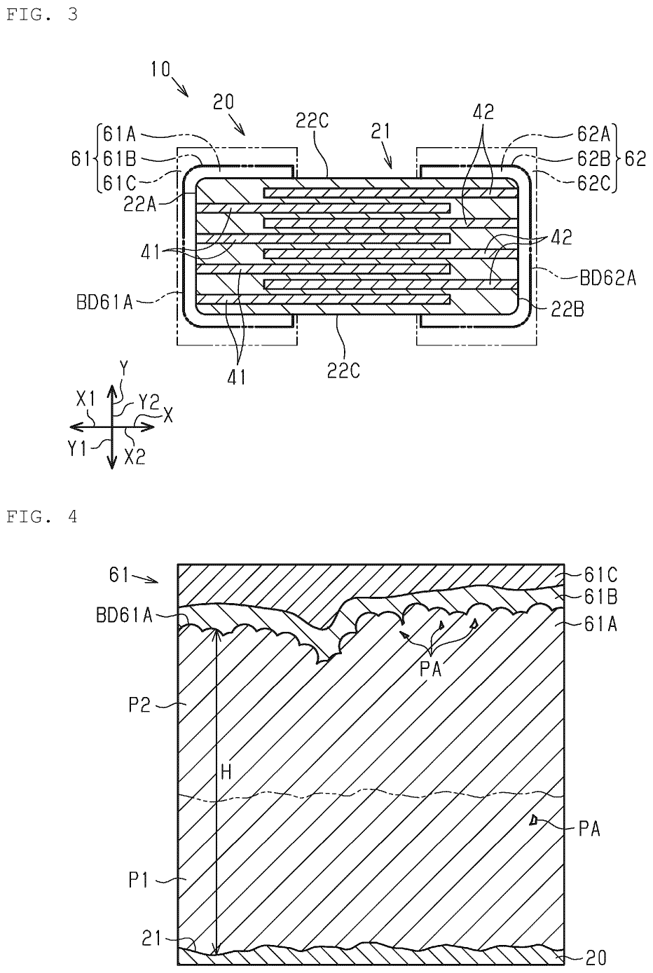

As illustrated in FIGS. 1 and 2, in the base body 20, the dimension in the direction along the first axis X is larger than the dimension in the direction along the third axis Z and the dimension in the direction along the second axis Y. The material of the base body 20 is a dielectric ceramic. Specifically, the material of the base body 20 contains BaTiO₃ as a main component. Alternatively, the material of the base body 20 may contain CaTiO₃, SrTiO₃, CaZrO₃, or the like as a main component. In addition, the material of the base body 20 may contain a Mn compound, a Co compound, a Si compound, a rare earth compound, or the like as an accessory component.

As illustrated in FIG. 3, the electronic component 10 includes four first internal electrodes 41 and four second internal electrodes 42. The first internal electrode 41 and the second internal electrode 42 are located inside the base body 20.

The material of the first internal electrode 41 is a conductive material. For example, the material of the first internal electrodes 41 is Ni. In addition, the material of the first internal electrode 41 may further contain metals such as Ni, Cu, Ag, Au, Pt, Sn, and Pd, or alloys containing these metals. The material of the second internal electrodes 42 is the same as the material of the first internal electrodes 41.

The first internal electrode 41 has a rectangular plate shape. The first internal electrode 41 has a principal surface orthogonal to the second axis Y. The second internal electrode 42 has the same rectangular plate shape as the first internal electrode 41. The second internal electrode 42 has a principal surface orthogonal to the second axis Y, as with the first internal electrode 41.

The dimension of the first internal electrode 41 in the direction along the first axis X is smaller than the dimension of the base body 20 in the direction along the first axis X. As illustrated in FIG. 1, the dimension of the first internal electrode 41 in the direction along the third axis Z is approximately ⅔ of the dimension of the base body 20 in the direction along the third axis Z. The dimension of the second internal electrode 42 in each of the directions is the same as that of the first internal electrode 41.

As illustrated in FIG. 3, the first internal electrodes 41 and the second internal electrodes 42 are located in a staggered manner in the direction along the second axis Y. More specifically, a total of eight internal electrodes are arranged alternately in the order of the first internal electrode 41 and the second internal electrode 42 toward the second negative direction Y2 from the side surface 22C that faces in the second positive direction Y1. According to the exemplary embodiment, each of the internal electrodes has an equal distance therebetween in the direction along the second axis Y.

As illustrated in FIG. 1, the four first internal electrodes 41 and the four second internal electrodes 42 are both located at the center of the base body 20 in the direction along the third axis Z. On the other hand, as illustrated in FIG. 3, the first internal electrodes 41 are located deviated to the first positive direction X1. The second internal electrodes 42 are located deviated to the first negative direction X2. Specifically, an end of the first internal electrode 41 on the first positive direction X1 side substantially coincides with an end of the base body 20 on the first positive direction X1 side. Therefore, the end of the first internal electrode 41 on the first positive direction X1 side is exposed from the first end surface 22A of the base body 20. The end of the first internal electrode 41 on the first negative direction X2 side is located inside the base body 20 and does not reach the end of the base body 20 on the first negative direction X2 side.

On the other hand, an end of the second internal electrode 42 on the first negative direction X2 side substantially coincides with an end of the base body 20 on the first negative direction X2 side. Therefore, the end of the second internal electrode 42 on the first negative direction X2 side is exposed from the second end surface 22B of the base body 20. The end of the second internal electrode 42 on the first positive direction X1 side is located inside the base body 20 and does not reach the end of the base body 20 on the first positive direction X1 side.

As illustrated in FIG. 3, the electronic component 10 includes a first external electrode 61 and a second external electrode 62. The first external electrode 61 and the second external electrode 62 are conductive as a whole. On the other hand, the first external electrode 61 and the second external electrode 62 contain no silver component. Here, “contains no silver component” allows a slight amount of silver component to be mixed into each external electrode in the manufacturing process. For example, when the atomic percent of the silver atom to all the atoms constituting each external electrode is less than 1 atm %, it is considered as “the external electrode contains no silver component”. This is because when the atomic percent of the silver atom is less than 1 atm %, significant migration that affects the characteristics of the electronic component 10 does not occur.

The first external electrode 61 includes a first underlying electrode 61A, a first mixed layer 61B, and a first metal layer 61C. In FIG. 3, the first mixed layer 61B is indicated by a thick line. The first underlying electrode 61A covers a part of the outer surface 21 of the base body 20, the part including the first end surface 22A. The first underlying electrode 61A is a five-face electrode that covers the first end surface 22A of the base body 20 and parts of the four side surfaces 22C thereof in the first positive direction X1. According to this exemplary embodiment, the material of the first underlying electrode 61A is copper and glass. In addition, the first underlying electrode 61A is a sintered body. Details of the first underlying electrode 61A will be described later.

The first metal layer 61C covers the outer surface BD61A of the first underlying electrode 61A. A part of the first metal layer 61C protrudes from the first underlying electrode 61A. Although not illustrated in the drawing, the first metal layer 61C has a two-layer structure of a nickel layer and a tin layer in this order from the first mixed layer 61B side.

The first mixed layer 61B is located between the first underlying electrode 61A and the first metal layer 61C. In other words, the first metal layer 61C covers the outer surface BD61A of the first underlying electrode 61A with the first mixed layer 61B interposed therebetween. Details of the first mixed layer 61B will be described later.

The second external electrode 62 includes a second underlying electrode 62A, a second mixed layer 62B, and a second metal layer 62C. In FIG. 3, the second mixed layer 62B is indicated by a thick line.

The second underlying electrode 62A covers a part of the outer surface 21 of the base body 20, the part including the second end surface 22B. The second underlying electrode 62A is a five-face electrode that covers the second end surface 22B of the base body 20 and parts of the four side surfaces 22C thereof in the first negative direction X2. According to this exemplary embodiment, the material of the second underlying electrode 62A is the same as the material of the first external electrode 61 and is copper and glass. In addition, as with the first underlying electrode 61A, the second underlying electrode 62A is a sintered body. Details of the second underlying electrode 62A will be described later.

The second metal layer 62C covers the outer surface BD62A of the second underlying electrode 62A. A part of the second metal layer 62C protrudes from the second underlying electrode 62A. Although not illustrated in the drawing, the second metal layer 62C has a two-layer structure of a nickel layer and a tin layer in this order from the second mixed layer 62B side, similarly to the first metal layer 61C.

The second mixed layer 62B is located between the second underlying electrode 62A and the second metal layer 62C. In other words, the second metal layer 62C covers the outer surface BD62A of the second underlying electrode 62A with the second mixed layer 62B interposed therebetween. Details of the second mixed layer 62B will be described later.

The second external electrode 62 does not reach the first external electrode 61 on the side surface 22C, and is disposed away from the first external electrode 61 in the direction along the first axis X. On the side surface 22C of the base body 20, the first external electrode 61 and the second external electrode 62 are not stacked in a central portion in the direction along the first axis X. In FIGS. 1 to 3, the first external electrode 61 and the second external electrode 62 are indicated by two-dot chain lines.

### <Configurations of First Underlying Electrode and Second Underlying Electrode>

Hereinafter, the first underlying electrode 61A will be representatively described below, the same applies to the second underlying electrode 62A. The first underlying electrode 61A contains copper and silicon.

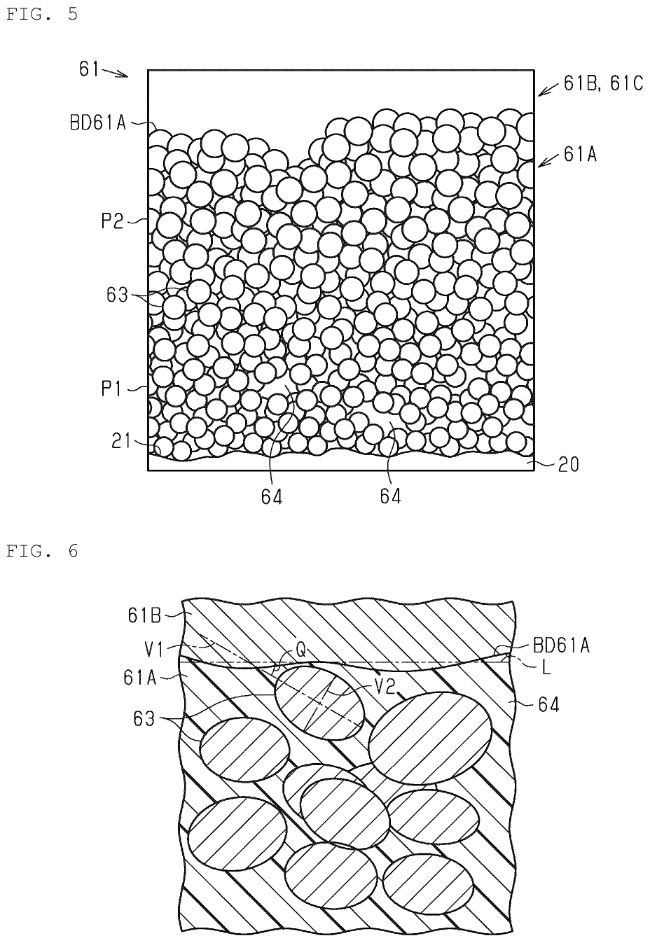

As illustrated in FIG. 5, at least a part of copper in the first underlying electrode 61A has spherical copper particles 63. In FIG. 5, only some of the copper particles 63 are denoted by reference numerals. In FIG. 5, each of the copper particles 63 is illustrated in a substantially circular shape, but may be elliptical or other amorphous particles.

In addition, the silicon in the first underlying electrode 61A is present as a silicone resin 64. It is to be noted that the silicone resin 64 is a polymer composed of a siloxane bond and a Si—C bond.

As illustrated in FIG. 4, the average value of the thickness H of the first underlying electrode 61A is about 700 nm. The thickness H of the first underlying electrode 61A is the shortest distance from the outer surface BD61A of the first underlying electrode 61A to the outer surface 21 of the base body 20. In FIG. 4, the thickness H at an arbitrary position is illustrated. In addition, in FIG. 4, illustration of the copper particles 63 and the silicone resin 64 in the first underlying electrode 61A is omitted, and they are illustrated as an integrated first underlying electrode 61A. The average value of the thickness H of the first underlying electrode 61A is calculated as follows. First, an arbitrary section of the first underlying electrode 61A is photographed with an electron microscope. Next, a range in a direction along the outer surface BD61A of the first underlying electrode 61A is specified for the photographed image. In this range, the sectional area of the first underlying electrode 61A is calculated by image processing for a measurement range of at least 5 μm or more. Then, the calculated sectional area of the first underlying electrode 61A in the measurement range is divided by the length, which is the measurement range, to calculate the average value of the thickness H of the first underlying electrode 61A. The outer surface BD61A of the first underlying electrode 61A is a boundary where the chemical component contained only in the first metal layer 61C is not observed. The outer surface BD61A of the first underlying electrode 61A substantially coincides with the interface following the edge of the copper particle 63 on the first metal layer 61C side in the section.

Here, it is assumed that the first underlying electrode 61A is bisected into a first part P1 located on the base body 20 side in the first underlying electrode 61A and a second part P2 located on the opposite side to the base body 20. The position where the first underlying electrode 61A is bisected is a position where the average value of the thickness H of the first underlying electrode 61A is bisected. In the present exemplary embodiment, the first part P1 is in a range of about 350 nm from the outer surface 21 of the base body 20 toward the outer surface BD61A of the first underlying electrode 61A.

The first underlying electrode 61A has voids PA without any synthetic resin such as a silicone resin 64 between the copper particles 63. The proportion of the voids PA in the second part P2 is larger than the proportion of the voids PA in the first part P1. In particular, in the entire first underlying electrode 61A, the voids PA is large in the vicinity of the outer surface BD61A of the first underlying electrode 61A. It is to be noted that the voids PA are schematically illustrated in FIG. 4.

The porosity measured as follows is used as the proportion of the voids PA in the second part P2 and the proportion of the voids PA in the first part P1. First, in a transmission electron microscope, the first part P1 is observed in a square range of 500 nm per side at a magnification of 200,000 times or more. In the range, the total area of positions without the copper particles 63 or the silicone resin 64, that is, the voids PA is calculated by image processing. Then, the porosity is calculated from the area ratio of the total area of the voids PA to the observation range. This process is repeated at four positions of the first part P1, and the average value of the porosities in the respective range is defined as the proportion of the voids PA in the first part P1. Similarly, the proportion of the voids PA in the second part P2 is calculated.

As illustrated in FIG. 5, the average value of the particle sizes of the copper particles 63 is different between the first part P1 and the second part P2. Specifically, the average value of the particle sizes of the copper particles 63 in the first part P1 is smaller than the average value of the particle sizes of the copper particles 63 in the second part P2. Specifically, the average value of the particle sizes of the first part P1 is 75 nm or less. The average value of the particle sizes of the second part P2 is 100 nm or more. Therefore, the ratio of the average value of the particle sizes of the copper particles 63 in the second part P2 to the average value of the particle sizes of the copper particles 63 in the first part P1 is 1.2 or more. In the first underlying electrode 61A as a whole, the particle size of the copper particles 63 decreases toward the base body 20 side in the first underlying electrode 61A.

The average value of the particle sizes of the copper particles 63 in the first part P1 is determined as follows. First, an image of the first underlying electrode 61A is acquired with an electron microscope at a magnification in a range including the outer surface BD61A of the first underlying electrode 61A and the boundary on the outer surface 21 side of the base body 20. Then, in the image, the first part P1 of a portion not including the boundary between the first part P1 and the outer surface 21 of the base body 20 and the position of bisecting the first underlying electrode 61A is enlarged, and the contours of the copper particles 63 is acquired by image processing. Then, the area of one copper particle 63 is calculated. Then, a circle having the calculated area is assumed. The diameter of the circle is calculated as the particle size of the copper particles 63. Then, the particle size is calculated for five or more copper particles 63, and the average value thereof is calculated. In this manner, the average value of the particle sizes of the copper particles 63 is calculated in five or more images, and the average value of the average values acquired from these five images is taken as the average value of the particle sizes of the copper particles 63 of the first part P1. Similarly, the average value of the particle sizes of the copper particles 63 in the second part P2 is calculated.

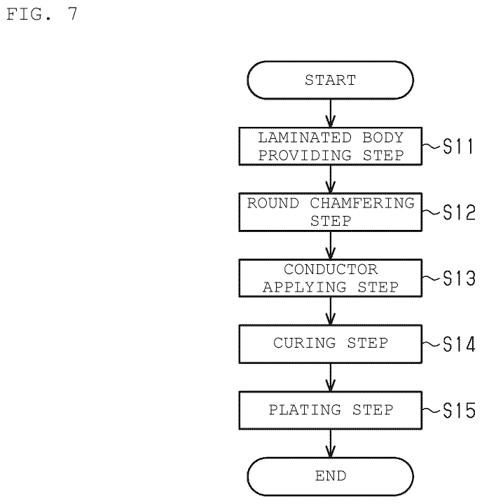

As illustrated in FIG. 6, it is assumed herein that a section is viewed in a specific section orthogonal to the outer surface BD61A of the first underlying electrode 61A. In the specific section, at least a part of the copper particles 63 has an elliptical shape. In FIG. 6, only some of the copper particles 63 are denoted by reference numerals.

In the specific section, the flattening ratio of the elliptical copper particles 63 is 0.5 or less. Further, the flattening ratio is calculated as follows. First, the contours of the copper particles 63 are acquired by image processing with an electron microscope. The image acquired is analyzed, and a half length of the longest line segment among the line segments connecting one edge and the other edge of one copper particle 63 is set as a long radius. In addition, half the length of the line segment orthogonal to the long radius and connecting one edge and the other edge of the copper particle 63 is defined as a short radius. When the long radius is a, the short radius is b, and the flattening ratio is F, the flattening ratio is calculated based on the following Equation 1.

F=1−(b/a) (Equation 1)

In addition, in the elliptical copper particles 63, an axis along the long radius is defined as a long axis V1. An axis along the short radius is defined as a short axis V2 of the copper particles 63. The acute angle Q formed by the long axis V1 of the elliptical copper particles 63 in the specific section and the axis L along the outer surface BD61A of the first underlying electrode 61A is 45 degrees or less. That is, the elliptical copper particles 63 are positioned in such a posture that the long axis V1 as a whole is along the outer surface BD61A of the first underlying electrode 61A. The axis L along the outer surface BD61A of the first underlying electrode 61A is determined as follows. For the image acquired in the specific section, an approximate straight line with respect to the outer surface BD61A of the first underlying electrode 61A is drawn. The approximate straight line can be obtained by, for example, a least squares method. An axis along this approximate straight line is defined as an axis L along the outer surface BD61A of the first underlying electrode 61A.

### <Mixed Layer>

The first mixed layer 61B and the second mixed layer 62B will be described. Hereinafter, the first mixed layer 61B will be representatively described, and the same applies to the second mixed layer 62B.

As illustrated in FIG. 4, the first mixed layer 61B is located between the first underlying electrode 61A and the first metal layer 61C. Although the boundary between the first underlying electrode 61A, the first mixed layer 61B, and the first metal layer 61C is virtually illustrated by a solid line, a clear boundary may not be observed.

The first mixed layer 61B is sufficiently smaller than the thickness H of the first underlying electrode 61A. For example, the thickness of the first mixed layer 61B is 10% or less of the thickness H of the first underlying electrode 61A. The first mixed layer 61B contains a chemical component that is not contained in the first underlying electrode 61A and is contained in the first metal layer 61C. Specifically, the chemical component is a nickel component which is a constituent component of the first metal layer 61C. In addition, the first mixed layer 61B contains a chemical component that is not contained in the first metal layer 61C and is contained in the first underlying electrode 61A. Specifically, the chemical components are a copper component and a silicone component which are constituent components of the first underlying electrode 61A. In the present exemplary embodiment, the constituent components of the first mixed layer 61B do not include components other than the constituent components of the first underlying electrode 61A and the constituent components of the first metal layer 61C. That is, the first mixed layer 61B is a layer formed by mixing the first underlying electrode 61A and the first metal layer 61C.

### <Method of Manufacturing Electronic Component>

Next, the method for manufacturing the electronic component 10 will be described.

As illustrated in FIG. 7, the method for manufacturing the electronic component 10 includes a laminated body providing step S11, a round chamfering step S12, a conductor applying step S13, a curing step S14, and a plating step S15.

First, in forming the base body 20, a laminate body is prepared in the laminated body providing step S11. Since the laminate body at this stage is in a state before round chamfering, the laminate body has a rectangular parallelepiped shape having the six planes. Specifically, for example, a plurality of ceramic sheets to be the base body 20 is prepared. Each of the sheets has a thin plate shape. A conductive paste to be the first internal electrode 41 is laminated on the sheet. A ceramic sheet to be the base body 20 is laminated on the paste. A conductive paste to be the second internal electrode 42 is laminated on the sheet. In this manner, the ceramic sheet and the conductive paste are alternately laminated. Then, the laminated sheets are subjected to pressure bonding in the stacking direction by for example die pressing. Thereafter, the sheets subjected to the pressure bonding are cut into a predetermined size to form an unfired laminated body. Thereafter, the unfired laminated body is fired at a high temperature to provide a laminated body.

Next, the round chamfering step S12 is performed. In the round chamfering step S12, the laminate body provided in the laminated body providing step S11 is round chamfered. By this step, the base body 20 in which the corner portion is round chamfered is obtained.

Next, the conductor applying step S13 is performed. In the conductor applying step S13, a conductor paste is applied to two positions of: a part of the first end surface 22A of the base body 20; and a part of the second end surface 22B of the base body 20, by an immersion method. Specifically, the conductor paste is applied so as to cover the entire region of the first end surface 22A and parts of the four side surfaces 22C. In addition, the conductor paste is applied so as to cover the entire region of the second end surface 22B and parts of the four side surfaces 22C. The conductor paste contains a copper component and a silicon component.

Further, the conductor paste is a complex ink. In addition, the conductor paste of the complex ink is prepared as follows. First, an amine compound such as 2-ethylhexylamine and an alcoholamine such as 2-amino-2-methylpropanol are mixed. Then, a silicon component such as a silicone resin is added thereto in an amount of 0.001-10 wt % with respect to the weight of Cu alone. Then, a metal salt is further added thereto and dissolved to prepare the conductor paste. More specifically, the conductor paste contains a copper component and the silicon component. The sintering onset temperature of the copper component is 170 degrees, and the curing onset temperature of the silicon component is 250 degrees.

Next, the curing step S14 is performed. Specifically, the base body 20 with the conductor paste applied thereto is heated in the curing step S14. According to the present exemplary embodiment, the base body 20 with the conductor paste applied thereto is heated in a nitrogen atmosphere. In the curing step S14, heating is performed in two stages. In the first stage, the temperature of the nitrogen atmosphere is maintained within a range of 200° C. to 400° C. In the second stage, the temperature of the nitrogen atmosphere is maintained within a range of 300° C. to 700° C. Thus, the conductor paste is fired. By the heating in the second stage, the bonding of some chemical components in the synthetic resin contained in the conductor paste is decomposed, and voids PA are generated.

In firing the conductor paste, the copper particles 63 and the silicone resin 64 are formed as follows. First, the copper component contained in the first underlying electrode 61A and the second underlying electrode 62A is started to be sintered. At the time when the copper component is started to be sintered, the silicon component is not cured with fluidity. Thus, the gaps of the copper component are filled with the silicon component. In addition, during sintering of the copper component, sintering of the copper component is started from the surface side of the conductor paste. At this time, the small copper particles 63 are united into the large copper particles 63 by Ostwald growth. As a result, the average value of the particle sizes of the copper particles 63 in the second part P2 is larger than the average value of the particle sizes of the copper particles 63 in the first part P1.

When the temperature is further increased to the curing onset temperature of the silicon component after the copper component is started to be sintered, the silicon component contained in the first underlying electrode 61A and in the second underlying electrode 62A is started to be cured. More specifically, the curing onset temperature of the silicon component is higher than the sintering onset temperature of the copper component. Then, the copper component is sintered, thereby producing the copper particles 63. In addition, the silicon component is cured, thereby producing the silicone resin 64. In addition, as described above, the curing onset temperature of the silicon component is higher than the sintering onset temperature of the copper component, thus providing the silicone resin 64 in the network form, which fills the gaps between the copper particles 63. As a result, the first underlying electrode 61A and the second underlying electrode 62A are formed as described above.

Next, the plating step S15 is performed. Parts of the first underlying electrode 61A and second underlying electrode 62A are subjected to electroplating. As a result, the first metal layer 61C is formed on the surface of the first underlying electrode 61A. In addition, the second metal layer 62C is formed on the surface of the second underlying electrode 62A. In the plating step S15, a part of the chemical component of the first metal layer 61C is mixed with the chemical component melted from the first underlying electrode 61A to form the first mixed layer 61B. The same applies to the second mixed layer 62B. Although not illustrated in the drawing, the first metal layer 61C and the second metal layer 62C are electroplated with two kinds, nickel and tin, to form a two-layer structure. In this way, the electronic component 10 is formed.

### Exemplary Advantageous Effects of Present Embodiment

The advantageous effects of the present exemplary embodiment will be described. Hereinafter, the effects of the first external electrode 61 will be representatively described, and the second external electrode 62 also produces the same advantageous effects.

(1) In the exemplary embodiment mentioned above, the first external electrode 61 contains no silver component. Therefore, according to the exemplary embodiment mentioned above, migration can be suppressed as compared with the case where the first external electrode 61 contains the silver component.

In the exemplary embodiment mentioned above, the average value of the particle sizes of the copper particles 63 in the second part P2 is larger than the average value of the particle sizes of the copper particles 63 in the first part P1. Since the particle size of the copper particles 63 in the second part P2 is large, the number of the copper particles 63 contained in the second part P2 is smaller than that in the first part P1. Therefore, in the second part P2, the contact area of one copper particle 63 with the other copper particles 63 is smaller than that in the first part P1. As a result, the mechanical strength of the second part P2 is lower than that of the first part P1. Therefore, when an impact is applied to the electronic component 10, a crack is more likely to occur in the second part P2 than in the first part P1. That is, the second part P2 plays a role of alleviating the influence of impact due to its own breakage. Therefore, when an impact acts on the electronic component 10, the second part P2 absorbs the impact, so that the crack and the like are less likely to occur in the base body 20. Furthermore, since the above-described impact relaxation effect can be exhibited in the second part P2 on the side far from the base body 20 in the first underlying electrode 61A, the impact is less likely to affect the base body 20. That is, according to the exemplary embodiment mentioned above, it is possible to suppress the impact on the base body 20 while suppressing the occurrence of migration.

(2) In the exemplary embodiment mentioned above, the ratio of the average value of the particle sizes of the copper particles 63 in the second part P2 to the average value of the particle sizes of the copper particles 63 in the first part P1 is 1.2 or more. According to this configuration, the impact relaxation effect in the second part P2 is more easily exhibited.

(3) In the exemplary embodiment mentioned above, the average value of the particle sizes of the copper particles 63 in the second part P2 is 100 nm or more. According to this configuration, since the average value of the copper particles 63 in the second part P2 is correspondingly large, the contact area between the copper particles 63 is reduced. That is, by intentionally decreasing the mechanical strength of the second part P2, the impact relaxation effect on the base body 20 can be further improved.

(4) In the exemplary embodiment mentioned above, the average value of the particle sizes of the copper particles 63 in the first part P1 is 75 nm or less. In this configuration, since the average value of the copper particles 63 in the first part P1 is correspondingly small, the contact area between the copper particles 63 increases. That is, according to the configuration mentioned above, by ensuring the mechanical strength of the first part P1, the crack occurred in the second part P2 can be suppressed from spreading to the entire first underlying electrode 61A including the first part P1.

(5) In the exemplary embodiment mentioned above, the acute angle Q formed by the long axis V1 of the elliptical copper particles 63 in the specific section and the axis L along the outer surface BD61A of the first underlying electrode 61A is 45 degrees or less. That is, the copper particles 63 are in such a posture as to be horizontally long in the direction along the outer surface BD61A of the first underlying electrode 61A. The crack is likely to occur in the gap between the copper particles 63. Therefore, when a crack occurs in the second part P2, there is a high possibility that the crack extends in a direction along the outer surface BD61A of the first underlying electrode 61A. Therefore, according to the configuration mentioned above, there is little possibility that when a crack occurs in the second part P2, the crack spreads to the first part P1.

(6) In the exemplary embodiment mentioned above, the proportion of the voids PA in the second part P2 is larger than the proportion of the voids PA in the first part P1. In a case where an impact acts on the first underlying electrode 61A, a crack is likely to occur starting from the voids PA. Therefore, according to the configuration mentioned above, the possibility that a crack occurs in the second part P2 is higher than in the first part P1. As a result, the impact relaxation effect by the second part P2 can be reliably obtained.

(7) In the exemplary embodiment mentioned above, the first mixed layer 61B contains a chemical component that is not contained in the first underlying electrode 61A and is contained in the first metal layer 61C. In addition, the first mixed layer 61B contains a chemical component that is not contained in the first metal layer 61C and is contained in the first underlying electrode 61A. In other words, the vicinity of the boundary between the first underlying electrode 61A and the first metal layer 61C is a first mixed layer 61B in which chemical components are mixed with each other. According to such a configuration, since a part of the first underlying electrode 61A is integrated with the first metal layer 61C, the first metal layer 61C is less likely to be peeled off from the first underlying electrode 61A.

### Modification Examples

The exemplary embodiment mentioned above and the following modification examples can be implemented in combination within a range that is not technically contradictory. In the case of a modification that can be commonly applied to the first external electrode 61 and the second external electrode 62, a modification related to the first external electrode 61 will be representatively described.
In the exemplary embodiment mentioned above, the electronic component 10 is not limited to any multilayer ceramic capacitor. For example, the electronic component 10 may be a piezoelectric component, a thermistor, an inductor, or the like.
In the exemplary embodiment mentioned above, the material of the base body 20 may be a dielectric substance, a piezoelectric substance, a magnetic substance such as ferrite, a composite of a synthetic resin and a metal, or the like.
The shape of the base body 20 is not limited to the example of the exemplary embodiment. For example, the base body 20 may have a polygonal columnar shape, other than a quadrangular columnar shape, having a central axis CA. Furthermore, the base body 20 may be the core of a wire-wound inductor component. For example, the core may have what is called a drum core shape. Specifically, the core may have a columnar winding core portion and a flange portion provided at each end of the winding core portion.
Of the outer surface 21 of the base body 20, a boundary portion between the adjacent planes may not have a chamfered shape. In this case, there is no curved surface at the boundary portion.
The shapes of the first internal electrode 41 and the second internal electrode 42 are not limited as long as they can ensure electrical conduction with the corresponding first external electrode 61 and second external electrode 62. The number of the first internal electrodes 41 and the second internal electrodes 42 is not limited, and may be smaller or larger than 4.
In the exemplary embodiment mentioned above, the first external electrode 61 may not have the first mixed layer 61B. That is, the boundary between the first underlying electrode 61A and the first metal layer 61C may be clearly separated. In the configuration without the first mixed layer 61B, the first metal layer 61C may cover at least a part of the first underlying electrode 61A.
In the exemplary embodiment mentioned above, the average value of the thickness H of the first underlying electrode 61A is not limited to the example of the exemplary embodiment mentioned above. The entire thickness of the first external electrode 61 including the first underlying electrode 61A may be designed in consideration of mechanical strength and the like required for the electronic component 10.
In the exemplary embodiment mentioned above, the configuration related to the first metal layer 61C in the first external electrode 61 may be omitted. The material of the first metal layer 61C is not limited to the example of the exemplary embodiment mentioned above. For example, the first metal layer 61C may be made of only nickel, or made of only tin, or may contain a material other than silver. For example, the material of the first metal layer 61C may be copper, silver, gold, palladium, and the like.
In the exemplary embodiment mentioned above, the synthetic resin is not limited to the silicone resin 64. For example, the synthetic resin may be a synthetic resin containing silicon such as a silicone oligomer. As described above, in a case where the synthetic resin contains silicon, the first underlying electrode 61A tends to be a dense film. The synthetic resin contained in the first underlying electrode 61A may contain nitrogen. For example, the synthetic resin may be a synthetic resin containing nitrogen such as urethane, epoxy, polyimide, polyimide amide, or polyamide. As described above, in a case where the synthetic resin contains nitrogen, the heat resistance of the first underlying electrode 61A is improved.

In addition, the synthetic resin is not limited to a resin containing nitrogen and silicon, and may be a resin such as acrylic, alkyd, or polyester, or may be another synthetic resin. In the first underlying electrode 61A, a composite of these nitrogen-containing synthetic resins, silicon-containing synthetic resins, and other synthetic resins may be adopted as the synthetic resin. In the first underlying electrode 61A, one kind of synthetic resin containing silicon and nitrogen may be adopted as the synthetic resin.
In the exemplary embodiment mentioned above, the average value of the particle sizes of the copper particles 63 in the first part P1 may be larger than 75 nm. The average value of the particle sizes of the copper particles 63 in the second part P2 may be smaller than 100 nm. The ratio of the average value of the particle sizes of the copper particles 63 in the second part P2 to the average value of the particle sizes of the copper particles 63 in the first part P1 may be less than 1.2. In order to more effectively obtain the effect described in (2), the ratio of the average value of the particle sizes of the copper particles 63 in the second part P2 to the average value of the particle sizes of the copper particles 63 in the first part P1 is preferably 1.4 or more, and more preferably 1.6 or more.
In the exemplary embodiment mentioned above, the acute angle Q formed by the long axis V1 of the copper particles 63 and the axis L along the outer surface BD61A of the first underlying electrode 61A may be larger than 45 degrees. In the exemplary embodiment mentioned above, the flattening ratio of the copper particles 63 may be larger than 0.5. In addition, in the specific section, all the copper particles 63 may have a substantially circular shape.
In the exemplary embodiment mentioned above, the proportion of the voids PA in the second part P2 may be the same as or smaller than the proportion of the voids PA in the first part P1. In the exemplary embodiment mentioned above, the first underlying electrode 61A may not have the voids PA.
The manufacturing process of the electronic component 10 in the exemplary embodiment mentioned above is not limited to the example of the exemplary embodiment mentioned above. For example, the base body 20 may be subjected to processing such as physical polishing.
In the exemplary embodiment mentioned above, the method for applying the conductor paste is not limited to the example of the exemplary embodiment mentioned above. For example, these pastes may be applied by printing, or may be applied by an inkjet method or the like.
In curing step S14 of the exemplary embodiment mentioned above, heating may be performed three or more times, or heating may be performed only once.
In the exemplary embodiment mentioned above, the sintering onset temperature of the copper component of the conductor paste and the curing onset temperature of the silicon component thereof are not limited to the example of the exemplary embodiment mentioned above.
In the plating step S15 of the exemplary embodiment mentioned above, the first metal layer 61C may be formed by other methods such as sputtering.
In the exemplary embodiment mentioned above, the conductor paste may be nano inks. In the case of nano inks, the inks are prepared as follows. Nanometal powders are dispersed in solvents containing cellosolves, carbitols, hydrocarbons, aromatics, and the like. Then, various silicone-modified resins, or silicone resins, sol-gel-based materials, or the like are added in an amount of 0.001-10 wt % with respect to the weight of Cu alone. The conductor pastes of the nano inks may be prepared in this manner, or by different methods.
In the exemplary embodiment mentioned above, the materials in the case of a complex ink for the conductor paste is not limited to the example of the exemplary embodiment mentioned above. For example, the amine compound may be any of primary amines, secondary amines, and tertiary amines, and furthermore, the number of N atoms is not limited. For example, the amine compound may be a primary amine such as an octylamine or a hexylamine, a secondary amine such as a di-n-butylamine, or a tertiary amine such as an N,N-dimethylhexylamine. In addition, the amine compound may be an alcoholamine, a diamine, or the like, and the positional relationship between the N atom and the OH group is not specified at the α-, β-, γ-position, or the like. Furthermore, the numbers of N and 0 atoms in one molecule are also not particularly limited. For example, the amine compound may be an α-hydroxylamine such as 2-dimethylaminoethanol or 2-ethylaminoethanol, or a β-hydroxylamine such as 3-amino-1-propanol or 4-amino-2-butanol. Furthermore, the amine compound may be a diamine such as an ethylenediamine, or a cyclic diamine such as piperazine. In addition, the silicon component may be, for example, various silicone-modified resins such as epoxy resins, polyester resins, and phenol resins, sol-gel materials, and the like. In addition, as the metal salt, metal salts obtained from formic acids, acetic acids, oxalic acids, other organic acids, and the like may be adopted. Examples of this type of metal salt include a copper formate anhydride.
In the exemplary embodiment mentioned above, the electronic component 10 may include a glass film. In such a case, for example, the glass film may be formed so as to cover the region of a part of the outer surface 21 of the base body 20. More specifically, the electrical connection between the first internal electrodes 41 and the first external electrode 61 and the electrical connection between the second internal electrodes 42 and the second external electrode 62 have only to be secured, if there is any glass film covering the base body 20.

### <Supplementary Note>

Technical ideas that can be derived from the exemplary embodiments and modification examples mentioned above will be described below.
[1] An electronic component including: a base body; an external electrode covering a part of an outer surface of the base body and including no silver component, wherein the external electrode includes an underlying electrode covering an outer surface of the base body, and the underlying electrode includes a copper particle and a synthetic resin, and when the underlying electrode is bisected into a first part located on a side closer to the base body and a second part located on a side opposite to the base body, an average value of particle sizes of the copper particle in the second part is larger than an average value of particle sizes of the copper particle in the first part.
[2] The electronic component according to [1], wherein
a ratio of the average value of particle sizes of the copper particle in the second part to the average value of particle sizes of the copper particles in the first part is 1.2 or more.
[3] The electronic component according to [1] or [2], wherein the average value of particle sizes of the copper particle in the second part is 100 nm or more.
[4] The electronic component according to any one of [1] to [3], wherein the average value of particle sizes of the copper particle in the first part is 75 nm or less.
[5] The electronic component according to any one of [1] to [4], wherein in a specific section orthogonal to an outer surface of the underlying electrode, at least a part of the copper particle has an elliptical shape, and an acute angle formed by a long axis of the copper particle and an axis along the outer surface of the underlying electrode is 45 degrees or less.
[6] The electronic component according to any one of [1] to [5], wherein the underlying electrode has a void in which the synthetic resin does not exist between the copper particle and the copper particle, and a proportion of the void in the second part is larger than a proportion of the void in the first part.
[7] The electronic component according to any one of [1] to [6], wherein the external electrode further includes a metal layer covering an outer surface of the underlying electrode, and a mixed layer located between the metal layer and the underlying electrode, and the mixed layer contains a chemical component that is not contained in the underlying electrode and is contained in the metal layer, and the mixed layer contains a chemical component that is not contained in the metal layer and is contained in the underlying electrode.

### DESCRIPTION OF REFERENCE SYMBOLS

BD61A: Outer surface
P1: First part
P2: Second part
PA: Void
10: Electronic component
20: Base body
21: Outer surface
61: First external electrode
61A: First underlying electrode
61B: First mixed layer
61C: First metal layer
63: Copper particle
64: Silicone resin

1. An electronic component comprising:
a base body;
an external electrode to cover a part of an outer surface of the base body and including no silver component, wherein
the external electrode includes an underlying electrode to cover an outer surface of the base body,
the underlying electrode includes copper particles and a synthetic resin, and
when the underlying electrode is bisected into a first part located on a side closest to the base body and a second part located on a side opposite to the base body, an average value of particle sizes of the copper particles in the second part is larger than an average value of particle sizes of the copper particles in the first part.

2. The electronic component according to claim 1, wherein a ratio of the average value of particle sizes of the copper particles in the second part to the average value of particle sizes of the copper particles in the first part is 1.2 or more.

3. The electronic component according to claim 1, wherein the average value of particle sizes of the copper particles in the second part is 100 nm or more.

4. The electronic component according to claim 2, wherein the average value of particle sizes of the copper particles in the second part is 100 nm or more.

5. The electronic component according to claim 1, wherein the average value of particle sizes of the copper particles in the first part is 75 nm or less.

6. The electronic component according to claim 2, wherein the average value of particle sizes of the copper particles in the first part is 75 nm or less.

7. The electronic component according to claim 3, wherein the average value of particle sizes of the copper particles in the first part is 75 nm or less.

8. The electronic component according to claim 1, wherein in a specific section orthogonal to an outer surface of the underlying electrode,
at least a part of the copper particle has an elliptical shape, and
an acute angle formed by a long axis of the copper particle and an axis along the outer surface of the underlying electrode is 45 degrees or less.

9. The electronic component according to claim 2, wherein in a specific section orthogonal to an outer surface of the underlying electrode,
at least a part of the copper particle has an elliptical shape, and
an acute angle formed by a long axis of the copper particle and an axis along the outer surface of the underlying electrode is 45 degrees or less.

10. The electronic component according to claim 3, wherein in a specific section orthogonal to an outer surface of the underlying electrode,
at least a part of the copper particle has an elliptical shape, and
an acute angle formed by a long axis of the copper particle and an axis along the outer surface of the underlying electrode is 45 degrees or less.

11. The electronic component according to claim 4, wherein in a specific section orthogonal to an outer surface of the underlying electrode,
at least a part of the copper particle has an elliptical shape, and
an acute angle formed by a long axis of the copper particle and an axis along the outer surface of the underlying electrode is 45 degrees or less.

12. The electronic component according to claim 5, wherein in a specific section orthogonal to an outer surface of the underlying electrode,
at least a part of the copper particle has an elliptical shape, and
an acute angle formed by a long axis of the copper particle and an axis along the outer surface of the underlying electrode is 45 degrees or less.

13. The electronic component according to claim 1, wherein
the underlying electrode has a void in which the synthetic resin does not exist between the copper particle and the copper particle, and
a proportion of the void in the second part is larger than a proportion of the void in the first part.

14. The electronic component according to claim 2, wherein
the underlying electrode has a void in which the synthetic resin does not exist between the copper particle and the copper particle, and
a proportion of the void in the second part is larger than a proportion of the void in the first part.

15. The electronic component according to claim 3, wherein
the underlying electrode has a void in which the synthetic resin does not exist between the copper particle and the copper particle, and
a proportion of the void in the second part is larger than a proportion of the void in the first part.

16. The electronic component according to claim 4, wherein
the underlying electrode has a void in which the synthetic resin does not exist between the copper particle and the copper particle, and
a proportion of the void in the second part is larger than a proportion of the void in the first part.

17. The electronic component according to claim 1, wherein
the external electrode further includes a metal layer to cover an outer surface of the underlying electrode, and a mixed layer located between the metal layer and the underlying electrode, and
the mixed layer includes a chemical component that is not included in the underlying electrode and is included in the metal layer, and the mixed layer includes a chemical component that is not included in the metal layer and is included in the underlying electrode.

18. The electronic component according to claim 2, wherein
the external electrode further includes a metal layer to cover an outer surface of the underlying electrode, and a mixed layer located between the metal layer and the underlying electrode, and
the mixed layer includes a chemical component that is not included in the underlying electrode and is included in the metal layer, and the mixed layer includes a chemical component that is not included in the metal layer and is included in the underlying electrode.

19. The electronic component according to claim 2, wherein
the external electrode further includes a metal layer to cover an outer surface of the underlying electrode, and a mixed layer located between the metal layer and the underlying electrode, and
the mixed layer includes a chemical component that is not included in the underlying electrode and is included in the metal layer, and the mixed layer includes a chemical component that is not included in the metal layer and is included in the underlying electrode.

20. The electronic component according to claim 3, wherein
the external electrode further includes a metal layer to cover an outer surface of the underlying electrode, and a mixed layer located between the metal layer and the underlying electrode, and
the mixed layer includes a chemical component that is not included in the underlying electrode and is included in the metal layer, and the mixed layer includes a chemical component that is not included in the metal layer and is included in the underlying electrode.
